(19) United States
(12) Patent Application Publication
(10) Pub. No.: US 2008/0052886 A1
(43) Pub. Date: Mar. 6, 2008

(54) DEGAS CHAMBER FOR FABRICATING SEMICONDUCTOR DEVICE AND DEGAS METHOD EMPLOYING THE SAME

(75) Inventor: Jong Guk KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/846,456

(22) Filed: Aug. 28, 2007

(30) Foreign Application Priority Data
Aug. 29, 2006 (KR) 10-2006-0082079

(51) Int. Cl. H01L 21/324; H01L 21/67

(52) U.S. Cl. 29/25.01; 438/799; 257/E21.211

(57) ABSTRACT

A degas apparatus for fabricating a semiconductor device is provided. The degas apparatus includes a chamber into which a wafer is loaded, a heating unit, disposed within the chamber, for heating the wafer to activate impurities remaining on the wafer, and a vacuum suction unit for sucking gases within the chamber by means of vacuum suction to discharge the activated impurities on the wafer to the outside. The degas apparatus also includes a hydrogen supply unit for supplying a hydrogen (H₂) gas to the chamber, which is heated by the heating unit, to remove and/or prevent formation of a metal oxide layer on the wafer.

### CROSS-REFERENCE TO RELATED APPLICATION

This application claims priority to Korean Application No. 10-2006-0082079, filed on Aug. 29, 2006, which is incorporated herein by reference in its entirety.

### BACKGROUND

1. Field of the Invention

The present invention relates, in general, to a degas chamber for fabricating semiconductor devices and a degas method employing the same; and, more particularly, to a degas chamber for fabricating semiconductor devices and a degas method employing the same, in which foreign substances, such as moisture existing on a wafer at the time of a degas process, can be removed, and in which unnecessary metal oxide layers formed on the wafer can be removed or prevented from being formed.

2. Description of Related Art

Fabricating semiconductor devices often includes a degas process. In general, a degas process refers to a process of activating and removing gaseous and/or liquid substances, such as moisture and O₂, through heating. Without removal, these substances can prevent a thin film from being formed on a wafer or they can change the characteristics of a thin film as the thin film is being formed by physical vapor deposition (PVD), chemical vapor deposition (CVD) or the like.

A conventional apparatus for performing the degas process used in fabricating semiconductor devices is described below with reference to the accompanying drawings.

FIG. 1 is a cross-sectional view of a conventional degas chamber for fabricating a semiconductor device.

As shown in FIG. 1, the conventional degas apparatus 10 includes a degas chamber 11 into which a wafer W is loaded for a degas process, heating unit 12 disposed within the chamber 11, and a vacuum suction unit 13 for sucking gases within the chamber 11 by means of vacuum suction.

The chamber 11 includes a plurality of support pins 11a for supporting the wafer W and an outlet 11b for the entrance and exit of the wafer W. The support pins 11a are disposed at the bottom of the chamber 11. The outlet 11b is disposed at one side of the chamber 11. Meanwhile, the chamber 11 is coupled to a buffer chamber 20 attached to the outlet 11b. The buffer chamber 20 includes a wafer transfer 21 for transferring the wafer W.

The vacuum suction unit 13 sucks gases within the chamber 11. In particular, the vacuum suction unit 13 sucks the gases of the chamber 11 through a vacuum suction tube 13a, which is disposed in the buffer chamber 20 and coupled to the chamber 11 through the outlet 11b, and discharges the sucked gases to the outside.

An operation of the conventional degas apparatus 10 for fabricating semiconductor devices is described below with reference to the flowchart of the degas process shown in FIG. 2.

Once the wafer W is loaded on the support pins 11a through the outlet 11b of the degas apparatus 10 by means of the wafer transfer 21 of the buffer chamber 20 in step S1, a temperature within the chamber 11 is raised by the heating unit 12 and the inside of the chamber 11 is maintained to a vacuum state by the vacuum suction unit 13 in step S2. As the temperature within the chamber 11 rises, substances, such as moisture and O₂ existing on the wafer W and having an adverse effect on the wafer during a subsequent fabrication process, are activated and then discharged to the outside by the vacuum suction unit 13.

After the degas process is finished as described above, the wafer W is unloaded from the degas apparatus 10 by the wafer transfer 21 of the buffer chamber 20 for the purpose of a subsequent process. In the case where a metal patterning process, such as a copper (Cu) seed deposition process employing a dual damascene method, is performed as a subsequent process, the wafer W on which the degas process has been performed undergoes a deposition process of a barrier layer of TaN or Ta and of a Cu seed. In this case, if the wafer W is maintained at a temperature of 150° C. or higher or oxygen is introduced due to a leakage of airtightness at the time of the degas process, a metal oxide layer (e.g., a Cu oxide (CuOₓ) layer when a metal pattern is formed of copper (Cu)) is easily formed on the wafer. The metal oxide layer causes an undesirable increase in the resistance value of the subsequently formed layer. Accordingly, it is necessary to remove the metal oxide layer prior to the next process.

In order to remove the metal oxide layer of the wafer, the wafer W is unloaded from the degas apparatus 10 prior to a barrier layer deposition process and is then loaded onto a plasma etch chamber so that the metal oxide layer of the wafer W may be removed by plasma etch using a hydrogen (H₂) gas as a process gas.

However, the process of removing the metal oxide layer from the wafer W is problematic in that it is very inconvenient like the degas process and requires lots of time and effort. Further, if airtightness is broken at the time of the degas process the metal oxide layer formed on the wafer W, such as the Cu oxide layer, cannot be removed even by plasma etch using the hydrogen (H₂) gas. Accordingly, semiconductor devices formed in this manner are frequently defective due to an increased resistance value in layers, such as a Cu seed layer, formed subsequent to the degas process.

### SUMMARY OF SOME EXAMPLE EMBODIMENTS

In general, example embodiments of the invention relate to a degas chamber for fabricating semiconductor devices and a degas method employing the same, in which foreign substances, such as moisture existing on a wafer at the time of a degas process, can be removed and unnecessary metal oxide layers on the wafer can be prevented or removed. As a result, additional processes, such as plasma etching to remove the metal oxide layers, can be omitted before a metal patterning process or a Cu seed deposition process. The yield of semiconductor devices can be increased accordingly, and although atmosphere might be introduced due to a leak during the degas process, the metal oxide layers can be prevented from being formed, so that the failure rate of semiconductor devices can be lowered.

In accordance with one example embodiment, there is provided a degas apparatus for fabricating a semiconductor device. The degas apparatus may include a chamber into which a wafer is loaded, a heating unit, disposed within the chamber, for heating the wafer to activate impurities remaining on the wafer, and a vacuum suction unit for sucking gases within the chamber by means of vacuum suction to discharge the activated impurities on the wafer to the outside. The degas apparatus also may include a hydrogen supply unit for supplying a hydrogen (H₂) gas to the chamber, which is heated by the heating unit, to remove and/or prevent formation of a metal oxide layer on the wafer.

In accordance with a second example embodiment the degas apparatus may further include a distribution supply path formed in a wafer stage disposed below the wafer to distribute the H₂ gas, which is supplied from the hydrogen supply unit, to a circumference of the wafer.

In accordance with a third example embodiment, there is provided a degas method of fabricating a semiconductor device, including loading a wafer into a degas chamber, heating the degas chamber in a vacuum state to discharge foreign substance remaining on the wafer to the outside, and supplying an H₂ gas to the heated degas chamber to remove and/or prevent formation of a metal oxide layer on the wafer.

### BRIEF DESCRIPTION OF THE DRAWINGS

Aspects of example embodiments of the invention will become apparent from the following description of example embodiments given in conjunction with the accompanying drawings, in which:

FIG. 1 is a cross-sectional view of a conventional degas apparatus for fabricating a semiconductor device;

FIG. 2 is a flowchart illustrating a conventional degas process of fabricating a semiconductor device;

FIG. 3 shows a configuration of a degas apparatus for fabricating a semiconductor device in accordance with an embodiment of the present invention;

FIG. 4 shows a configuration of a degas apparatus for fabricating a semiconductor device in accordance with another embodiment of the present invention; and

FIG. 5 is a flowchart illustrating a degas process of fabricating a semiconductor device in accordance with the present invention.

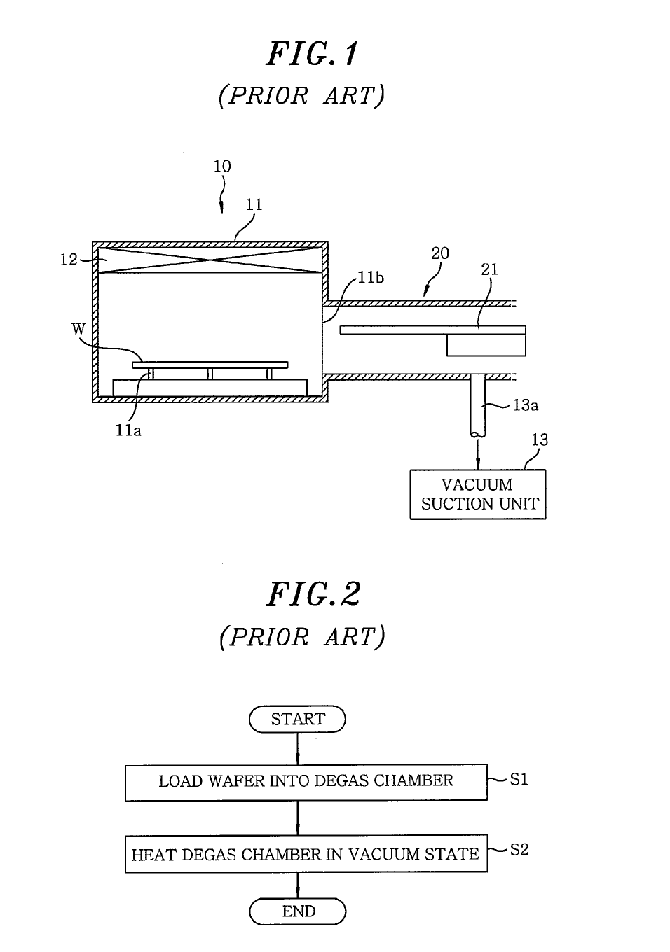

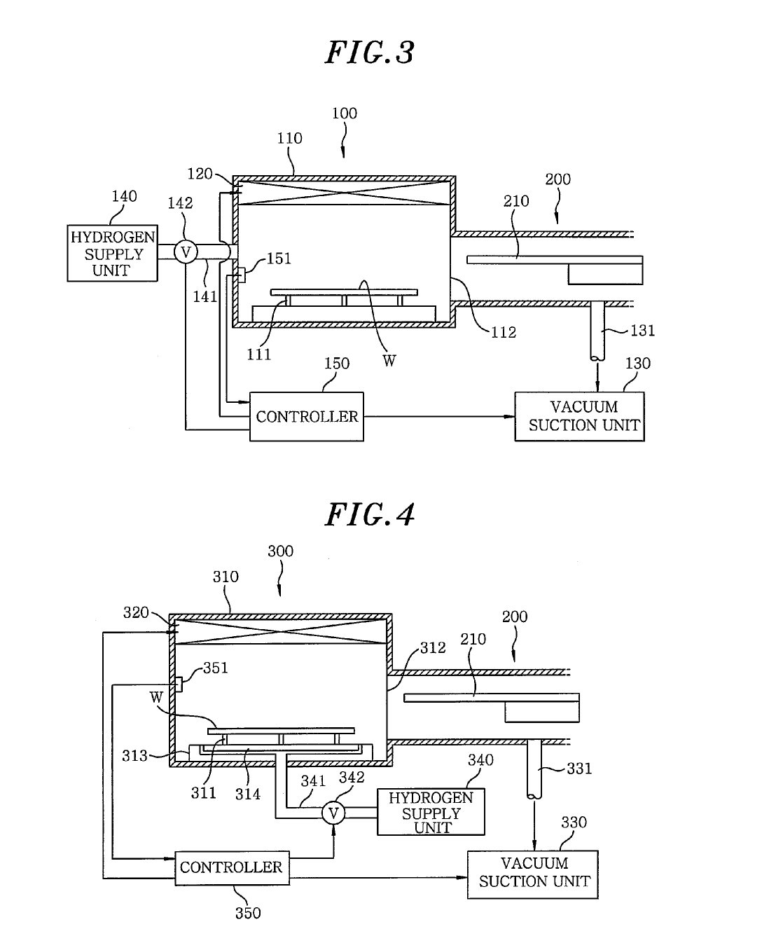

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

FIG. 3 shows a configuration of a degas apparatus for fabricating a semiconductor device in accordance with an embodiment of the present invention.

As shown in FIG. 3, the degas apparatus 100 according to the present embodiment may include a degas chamber 110 into which a wafer W is loaded for a degas process, a heating unit 120 disposed within the chamber 110, a vacuum suction unit 130 for sucking gases within the chamber 110 by means of vacuum suction, and a hydrogen supply unit 140 for supplying a hydrogen (H₂) gas to the chamber 110.

The chamber 110 may include a plurality of support pins 111 for supporting the wafer W and an outlet 112 for the entrance and exit of the wafer W. The support pins 111 may be disposed at the bottom of the chamber 110. The outlet 112 may be disposed at one side of the chamber 110. Also, a buffer chamber 200 equipped with a wafer transfer 210 for transferring the wafer W can be coupled to the outlet 112.

The heating unit 120 can include a heater, e.g., a halogen lamp or the like, that heats the wafer W by radiating heat. Thus, impurities such as moisture and oxygen remaining on the wafer W are activated by the heat.

The vacuum suction unit 130 may apply vacuum suction to gases within the chamber 110 to discharge the activated impurities to the outside. For example, the vacuum suction unit 130 can suck gases within the chamber 110 and activated impurities on the wafer W through a vacuum suction tube 131, which is disposed in the buffer chamber 200 and coupled to the chamber 110 through the outlet 112, and discharge them to the outside.

The hydrogen supply unit 140 supplies an H2 gas to the chamber 110 heated by the heating unit 120, so that a metal oxide layer on the wafer W (for example, a Cu oxide (CuOx) layer in the case of a Cu metal line process employing a dual damascene method) can be removed.

The degas apparatus 100 can further include a temperature sensor 151 and a controller 150 so that the H2 gas is supplied only when a temperature within the chamber 110 is constant.

The temperature sensor 151 may be disposed within the chamber 110. The temperature sensor 151 senses a temperature within the chamber 110 and may output a sensed temperature to the controller 150 as a sensed signal.

The controller 150 may receive a sensed signal from the temperature sensor 151 and may control the supply of hydrogen (H2) of the hydrogen supply unit 140. To this end, the controller 150 may control an open/close valve 142 to open or close a hydrogen supply tube 141 that provides a path along which the H2 gas is supplied from the hydrogen supply unit 140 to the chamber 110.

Further, the controller 150 may control the hydrogen supply unit 140 to open or close the open/close valve 142 so that the H2 gas is supplied to the chamber 110 when a temperature sensed by the temperature sensor 151 is in an appropriate range. For example, a temperature within the range from about 320° C. to about 380° C. may be required for the reaction of the metal oxide layer and the H2 gas. Unnecessary consumption of the H2 gas may thus be avoided because the H2 gas supplied to an unheated chamber 110 is discharged to the outside without removing or preventing formation of a metal oxide layer.

FIG. 4 shows a configuration of a degas apparatus 300 for fabricating a semiconductor device in accordance with another embodiment of the present invention.

The degas apparatus 300 according to the present embodiment may include a plurality of support pins 311 for supporting a wafer W, which may be loaded through an outlet 312, at the bottom of a chamber 310. The degas apparatus 300 may also include a heating unit 320 disposed within the chamber 310, a vacuum suction unit 330 for applying vacuum suction to gases within the chamber 310 through a vacuum suction tube 331, and a hydrogen supply unit 340 for supplying a hydrogen (H2) gas to the chamber 310. The controller 350 may control the hydrogen supply unit 340 by controlling an open/close valve 342 for opening or closing a hydrogen supply tube 341 depending on a temperature of a temperature sensor 351.

The degas apparatus 300 according to the present embodiment may further include a distribution supply path 314 disposed in a wafer stage 313 on which the support pins 311 are disposed within the chamber 310, unlike the previous embodiment. The distribution supply path 314 may serve to supply the H2 gas, which is supplied from the hydrogen supply unit 340, to the circumference of the wafer W.

The distribution supply path 314 may be coupled to the hydrogen supply tube 341 of the hydrogen supply unit 340, and may comprise one path that diverges into a plurality of paths so that the H2 gas can be supplied to a plurality of points in the external edges of the wafer W on the wafer stage 313. Thus, the H2 gas can be supplied to the wafer W uniformly and rapidly.

An operation of the degas chamber for fabricating semiconductor devices in accordance with the present embodiment is described below in detail along with a degas process of fabricating semiconductor devices according to the present invention.

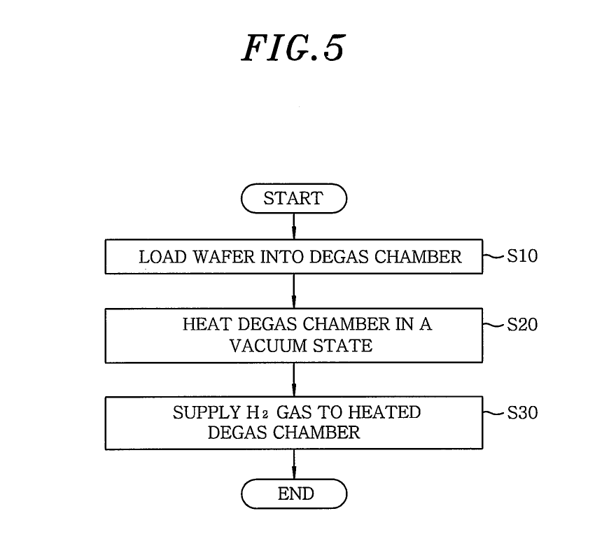

FIG. 5 is a flowchart illustrating a degas process of fabricating a semiconductor device in accordance with the present invention.

As shown in FIG. 5, the degas process in accordance with the present invention includes loading the wafer W into the degas apparatus 100 (step S10), heating the degas apparatus 100 in a vacuum state (step S20), and supplying a hydrogen (H2) gas to the heated degas apparatus 100 to remove and/or prevent formation of a metal oxide layer (step S30).

In the step S10 of loading the wafer W into the degas apparatus 100, the wafer W may be seated on the support pins 111 within the chamber 110 through the outlet 112 by means of the wafer transfer 210 of the buffer chamber 200.

In the step S20 of heating the degas apparatus 100 in a vacuum state, once the wafer W is seated on the support pins 111 within the chamber 110, the inside of the chamber 110 and the wafer W may be heated by the heating unit 120. The vacuum suction unit 130 sucks gases within the chamber 110 through the vacuum suction tube 131 by means of vacuum suction. Accordingly, impurities, such as moisture or oxygen remaining on the wafer W, are activated, sucked in a vacuum state and then discharged to the outside.

In the step S30 of supplying the H2 gas to the heated degas apparatus 100 to remove and/or prevent formation of the metal oxide layer, the H2 gas may be supplied from the hydrogen supply unit 140 to the degas apparatus 100, which has been heated by the heating unit 120, through the hydrogen supply tube 141. Thus, a metal oxide layer, for example, a Cu oxide (CuOx) layer in the case of a dual damascene process, may react with the H2 gas on the heated wafer W, so that the metal oxide layer such as the Cu oxide (CuOx) layer is removed and/or prevented from forming.

Furthermore, in the degas apparatus 300 according to the FIG. 4 embodiment of the present invention, the H2 gas may be supplied to a plurality of points outside the edges of the wafer W by means of the distribution supply path 314. Accordingly, the H2 gas can be supplied to the wafer W uniformly and rapidly, thus efficiently removing the metal oxide layer.

In the step S30 of removing the metal oxide layer, the controller 150 may open the open/close valve 142 when a temperature of the degas apparatus 100, as indicated by the temperature sensor 151, reaches about 320° C. to about 380° C. so that the H2 gas can be supplied from the hydrogen supply unit 140 to the chamber 110. As described above, when the temperature of the degas apparatus 100 is in the range from about 320° C. to about 380° C. at which a metal oxide layer, such as a Cu oxide (CuOx) layer, can react to the H2 gas, the H2 gas may be supplied to the chamber 110. Consequently, unnecessary consumption of the H2 gas can be avoided since the H2 gas supplied to an unheated chamber 110 is discharged to the outside.

As described above, according to the apparatus and method embodiments of the present invention, foreign substance, such as moisture existing on the wafer at the time of a degas process, can be removed and/or prevented and unnecessary metal oxide layers on the wafer can be removed and/or prevented. Thus, an additional process, such as plasma etch for removing the metal oxide layers, can be omitted before a metal patterning process as well as a Cu seed deposition process, and the yield of semiconductor devices can be increased accordingly. Further, although atmosphere may be introduced due to a chamber leak during the degas process, formation of the metal oxide layer can be prevented. Accordingly, the failure rate of semiconductor devices can be lowered.

While the invention has been shown and described with respect to the embodiments, it will be understood by those skilled in the art that various changes and modifications may be made without departing from the scope of the invention as defined in the following claims.

What is claimed is:

1. A degas apparatus for fabricating a semiconductor device, comprising:
a chamber into which a wafer is loaded;
a heating unit, disposed within the chamber, adapted to heat the wafer to activate impurities remaining on the wafer;
a vacuum suction unit adapted to apply vacuum suction to gases within the chamber to discharge the activated impurities on the wafer to the outside; and
a hydrogen supply unit adapted to supply a hydrogen (H₂) gas to the chamber, which is heated by the heating unit, to remove and/or prevent formation of a metal oxide layer on the wafer.

2. The degas apparatus of claim 1, further comprising:
a temperature sensor, disposed within the chamber, adapted to sense a temperature of the chamber and to output the temperature as a sensed signal; and
a controller adapted to receive receive the sensed signal from the temperature sensor and to control the supply of the H₂ gas of the hydrogen supply unit.

3. The degas apparatus of claim 2, wherein the controller is adapted to control the hydrogen supply unit to supply the H₂ gas to the chamber when the temperature sensed by the temperature sensor ranges from about 320° C. to about 380° C.

4. A degas apparatus for fabricating a semiconductor device, comprising:
a chamber into which a wafer is loaded;
a heating unit, disposed within the chamber, adapted to heat the wafer to activate impurities remaining on the wafer;
a vacuum suction unit adapted to apply vacuum suction to gases within the chamber to discharge the activated impurities on the wafer to the outside; and
a hydrogen supply unit adapted to supply a hydrogen (H₂) gas to the chamber, which is heated by the heating unit, to remove and/or prevent formation of a metal oxide layer on the wafer,
wherein the chamber includes a distribution supply path formed in a wafer stage disposed below the wafer to distribute the H₂ gas supplied from the hydrogen supply unit to a circumference of the wafer.

5. The degas apparatus of claim 4, wherein the distribution supply path is coupled to the hydrogen supply unit and comprises one path that diverges into a plurality of paths to supply the H₂ gas to a plurality of points on the circumference of the wafer.

6. The degas apparatus of claim 4, further comprising:
a temperature sensor, disposed within the chamber, adapted to sense a temperature of the chamber and to output the temperature as a sensed signal; and
a controller adapted to receive the sensed signal from the temperature sensor and to control the supply of the H₂ gas of the hydrogen supply unit.

7. The degas apparatus of claim 5, wherein the controller is adapted to control the hydrogen supply unit to supply the H₂ gas to the chamber when the temperature sensed by the temperature sensor ranges from about 320° C. to about 380° C.

8. A degas method of fabricating a semiconductor device, comprising:
(a) loading a wafer into a degas chamber;
(b) heating the degas chamber in a vacuum state to discharge foreign substance remaining on the wafer to the outside; and
(c) supplying an H₂ gas to the heated degas chamber to remove and/or prevent formation of a metal oxide layer on the wafer.

9. The degas method of claim 8, wherein, in the step (b), the foreign substance remaining on the wafer is discharged to the outside by sucking gases within the degas chamber by means of vacuum suction.

10. The degas method of claim 8, wherein, in the step (c), the H₂ gas is supplied when the temperature of the degas chamber reaches about 320° C. to about 380° C.
